(19) United States
(12) Patent Application Publication
(10) Pub. No.: US 2009/0026630 A1
(43) Pub. Date: Jan. 29, 2009

(54) SEMICONDUCTOR DEVICE AND METHOD FOR MANUFACTURING SAME

(75) Inventors: Isao OZAWA, Chigasaki-Shi (JP); Youichi Oota, Hsinchu-City (TW)

Correspondence Address: OBLON, SPIVAK, MCCLELLAND MAIER & NEUSTADT, P.C., 1940 DUKE STREET, ALEXANDRIA, VA, 22314, US

(73) Assignee: KABUSHIKI KAISHA TOSHIBA, Tokyo (JP)

(21) Appl. No.: 12/179,891

(22) Filed: Jul. 25, 2008

(30) Foreign Application Priority Data
Jul. 26, 2007 (JP) 2007-194915

(51) Int. Cl. H01L 21/50; H01L 23/538

(52) U.S. Cl. 257/777; 438/107; 257/E23.169; 257/E21.499

(57) ABSTRACT

The present invention provides a semiconductor device capable of preventing chip cracks in a manufacturing process as much as possible, wherein the semiconductor device includes: a substrate main body provided with an inner surface internal to the semiconductor device and an outer surface external to the semiconductor device opposed to each other; an external wiring pattern having a pattern for non-external terminals covered with an insulating material and a pattern for external terminals electrically conductive to the outside formed at least on the outer surface of the substrate main body using a conductive material and electrically connected to each other; an insulating film for covering the pattern for non-external terminals of the external wiring pattern; a metal-plated layer adapted to constitute external terminals in conjunction with the pattern for external terminals and formed on the pattern for external terminals of the external wiring pattern, so as to reduce or eliminate a difference in step with respect to the insulating film; a semiconductor chip mounted on the inner surface of the substrate main body; and a molding resin for molding the inner surface of the substrate main body along with the semiconductor chip.

### CROSS-REFERENCE TO RELATED APPLICATION

This application is based upon and claims the benefit of priority from prior Japanese Patent Application No. 2007-194915, filed on Jul. 26, 2007, the entire contents of which are incorporated herein by reference.

### BACKGROUND OF THE INVENTION

1. Field of the Invention

The present invention relates to a semiconductor device, such as a NAND memory card, and a method for manufacturing the semiconductor device.

2. Background Art

In recent years, the memory capacity of NAND memory cards, such as an SD card, a miniSD card, a microSD card and an XD picture card, has been on the constant increase. Methods for increasing the memory capacity include increasing the number of NAND memory chips to be mounted on a semiconductor device to increase the capacity thereof, in addition to increasing the capacity of a NAND memory chip itself. A chip stacking method in which chips are stacked on top of each other is available to avoid increasing the size of a memory card when increasing the number of chips to be mounted. For example, Japanese Patent Laid-Open No. 2006-313798 describes a semiconductor device in which chips are stacked.

### SUMMARY OF THE INVENTION

According to one aspect of the present invention, there is provided a semiconductor device including:

a substrate main body provided with an inner surface internal to the semiconductor device and an outer surface external to the semiconductor device opposed to each other;

an external wiring pattern having a pattern for non-external terminals covered with an insulating material and a pattern for external terminals electrically conductive to the outside formed at least on the outer surface of the substrate main body using a conductive material and electrically connected to each other;

an insulating film for covering the pattern for non-external terminals of the external wiring pattern;

a metal-plated layer adapted to constitute external terminals in conjunction with the pattern for external terminals and formed on the pattern for external terminals of the external wiring pattern, so as to reduce or eliminate a difference in step with respect to the insulating film;

a semiconductor chip mounted on the inner surface of the substrate main body; and

a molding resin for molding the inner surface of the substrate main body along with the semiconductor chip.

### BRIEF DESCRIPTION OF THE DRAWINGS

FIG. 1A is an external view of a NAND memory card according to an embodiment of the present invention;

FIG. 1B is an external view of the NAND memory card shown in FIG. 1A taken from the external terminal side;

FIG. 2A is a block diagram illustrating the circuit configuration of the NAND memory card;

FIG. 2B is a block diagram illustrating the circuit configuration of a different NAND memory card;

FIG. 3 is a schematic cross-sectional view of a NAND memory card;

FIG. 4A is a schematic view illustrating the detailed structure of a substrate package;

FIG. 4B is a schematic view illustrating the detailed structure of a different substrate package;

FIG. 4C is a schematic view illustrating the detailed structure of another different substrate package;

FIG. 5A is a cross-sectional view of a portion near a boundary between external terminals and a solder resist;

FIG. 5B is a cross-sectional view of a portion near a boundary between external terminals and a solder resist in a different case;

FIG. 6A is an enlarged plan view of the portion near the boundary between the external terminals and the solder resist;

FIG. 6B is a cross-sectional view taken along the line A-A′ of FIG. 6A;

FIG. 6C is an enlarged plan view of a portion near a boundary between external terminals and a solder resist in a different case;

FIG. 6D is an enlarged plan view of a portion near a boundary between external terminals and a solder resist in another different case;

FIG. 6E is an enlarged plan view of a portion near a boundary between external terminals and a solder resist in yet another different case;

FIG. 6F is an enlarged plan view of a portion near a boundary between external terminals and a solder resist in still another different case;

FIG. 6G is an enlarged plan view of a portion near a boundary between external terminals and a solder resist in still another different case;

FIG. 7A is a schematic view illustrating a condition of an intermediate NAND chip in a molding step according to an embodiment of the present invention;

FIG. 7B is schematic view illustrating another condition of the intermediate NAND chip in a molding step according to an embodiment of the present invention; and

FIG. 8 is a schematic view illustrating a chip crack in a molding step that the present inventor has learned.

### DESCRIPTION OF THE EMBODIMENTS

An explanation will be made of the background that has led the present inventor into accomplishing the present invention, prior to describing embodiments of the present invention.

The thickness of each type of memory card is specified by a standard and, therefore, memory cards have limits in the thickness direction thereof. Consequently, the thickness of each chip needs to be made thinner as the number of stacked chips increases. Accordingly, chips have been thinned down to the extent of approximately 100 to 150 μm. As the result of chips having been thinned down to this extent, chip strength degreases and chip cracks may occur in a process of manufacturing a semiconductor device.

The present inventor has learned independently that if, in particular, there is a difference in step between plated external terminals extending from a substrate to be mounted with chips and a solder resist (highly heat-resistant organic insulating material) for protecting copper interconnects adjacent to the terminals, then the substrate as a whole sags and a chip or chips tend to crack at the step in a molding step. This technical problem is what the present inventor has recognized independently as described above, and is a problem of which any other persons skilled in the art are not even aware. As heretofore known, this molding step is carried out by holding a substrate, in which chips have been mounted and wire-bonded, between upper and lower dies and resin-sealing the substrate by pressure-injecting a molding resin, thereby protecting the substrate, chips, bonding wires and the like.

As one of measures for preventing such chip cracks, the present inventor has conceived of adopting a structure in which the external terminals and copper interconnects are all gold-plated, without using a solder resist. However, the present inventor has thought that this measure might give rise to another problem that the cost of the substrate increases and a card becomes expensive since the used amount of gold plating increases.

As another preventive measure, the present inventor has conceived of adopting a method for coating a solder resist and performing metal plating after molding. However, the present inventor has considered that this method may be infeasible in practice since the copper interconnects of the substrate oxidize as the result of the substrate being exposed to a high temperature in the molding step. Another reason is that there is the possibility of destroying chips by a large current generated at the time of metal plating. What has been described above is the present inventor's own technical recognition and is not knowable to any other persons skilled in the art.

Hereinafter, embodiments of the present invention will be described.

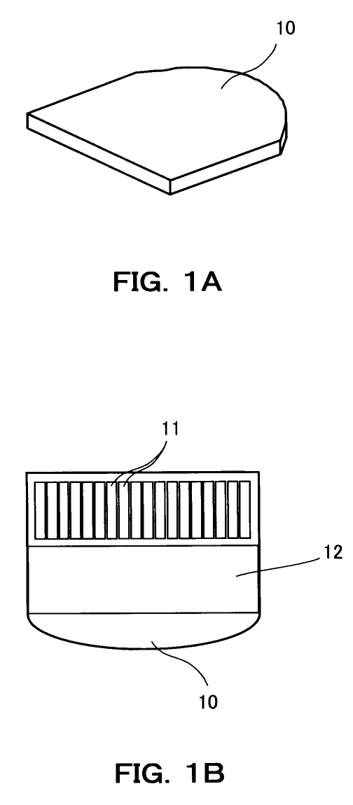

FIG. 1A shows an external view of a NAND memory card 10 taken from the top surface thereof. As shown in FIG. 1B, external terminals 11 are formed in an exposed manner on the rear surface of the NAND memory card 10. A label 12 for protecting the solder resist of the substrate is attached to the NAND memory card 10 in an inward direction of the external terminals 11.

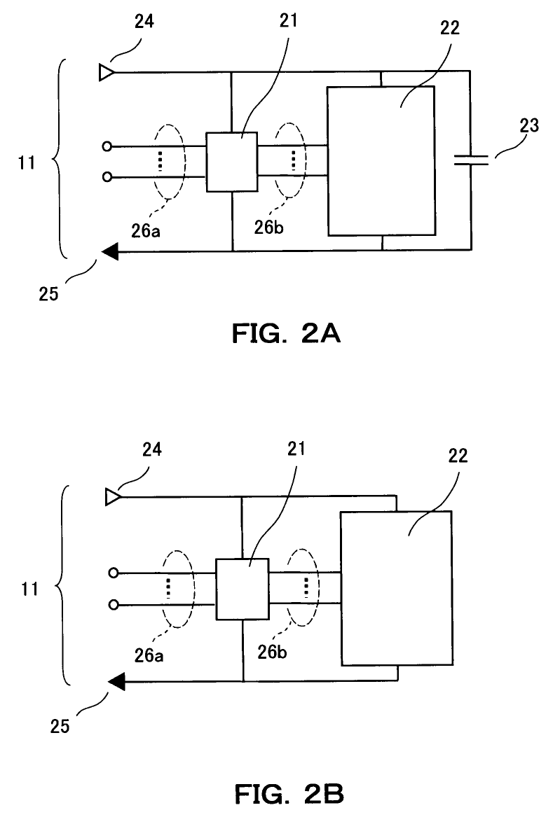

FIG. 2A shows the circuit configuration of the NAND memory card 10. The circuit of the card 10 has a controller chip 21, a NAND memory chip 22 and a capacitor 23. The external terminals 11 of the card 10 include a power supply terminal 24, a grounding terminal 25 and input-output signal terminals 26a. As can be seen from FIG. 2A, the power supply terminal 24 and the grounding terminal 25 are respectively connected to the power supply and ground sides of the controller chip 21 and the NAND memory chip 22. The capacitor 23 is connected between the power supply terminal 24 and the grounding terminal 25. The capacitor 23 is a so-called “pasukon” (bypass condenser) used to protect the memory chip and the like from supply voltage fluctuations. The input-output signal terminals 26a are connected to the external input-output signal terminals of the controller chip 21. Likewise, the respective input-output signal terminals 26b of the controller chip 21 and the NAND memory chip 22 are connected therebetween in order to exchange signal data.

FIG. 2B is a circuit diagram in a modification example of the device shown in FIG. 2A, wherein the circuit diagram differs from that of the device shown in FIG. 2A in that the former does not have the capacitor 23. In the circuit of FIG. 2B, the same circuit elements as those of the circuit of FIG. 2A are denoted by like numerals and will not be explained again.

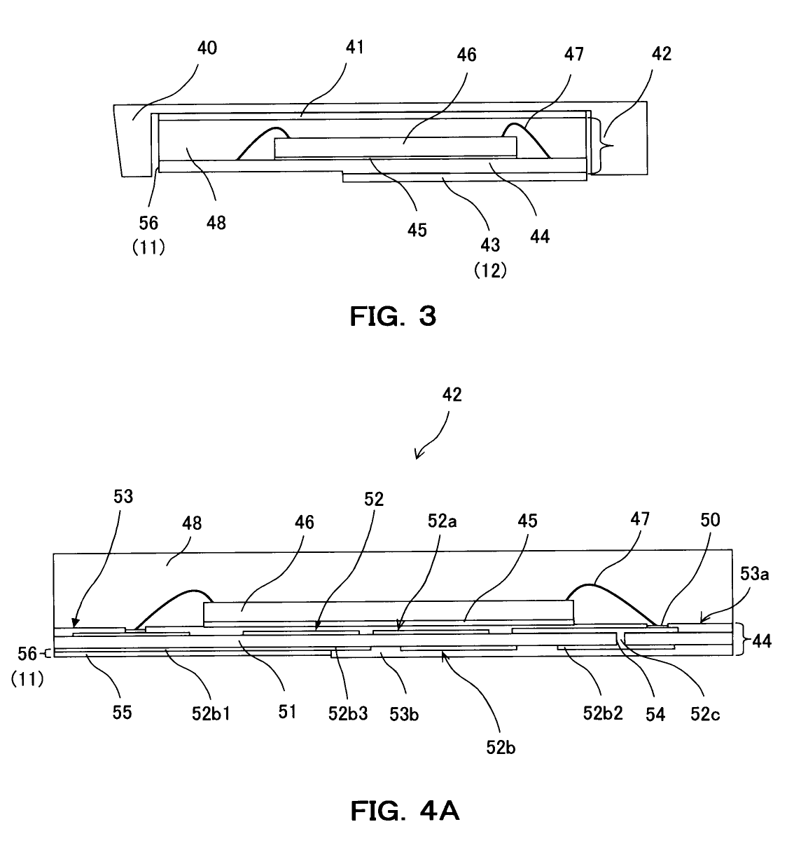

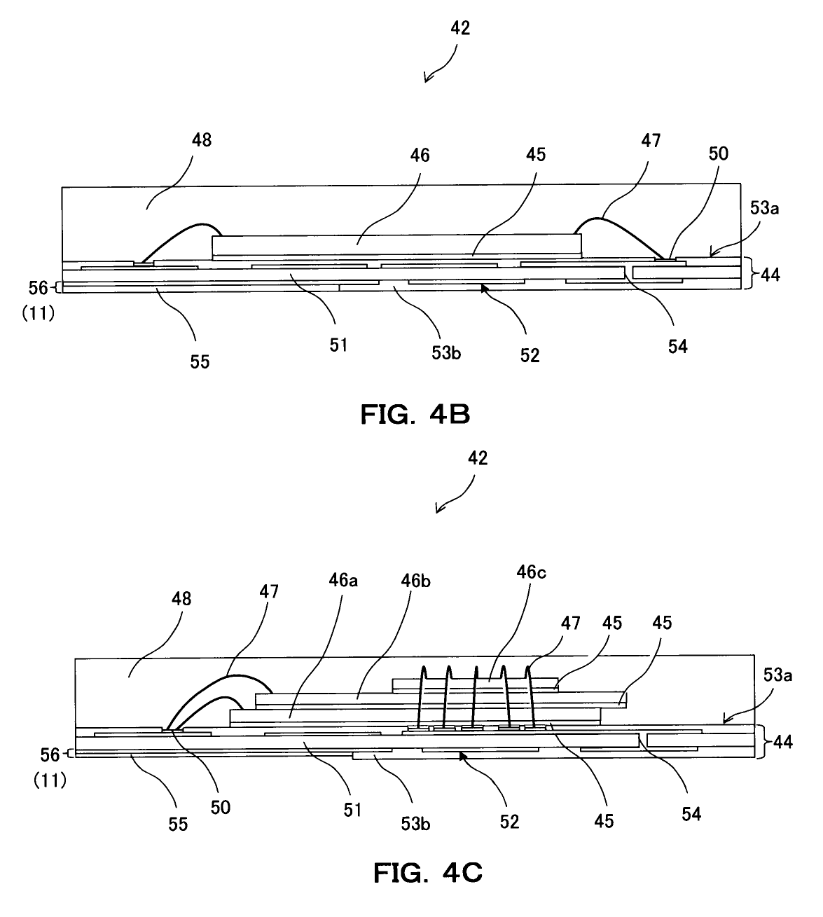

FIG. 3 shows the cross-section structure of the card shown in FIG. 2A as a schematic view from which the capacitor 23 is excluded. The cross-sectional view of the card shown in FIG. 2B is illustrated in the same way as FIG. 3. In FIG. 3, the card is provided with a case 40, an adhesive 41, a substrate package 42 and a label 43 (12). The case 40 and the substrate package 42 are bonded together using the adhesive 41. The label 43 (12) is attached to a surface (rear surface) opposite to a bonding face between the case 40 and the substrate package 42. This label 43 (12) is attached to a solder resist (53b in FIG. 4A) adjacent to the external terminals 11 in order to protect the solder resist 53b.

As can be seen from FIG. 3, the substrate package 42 is provided with a substrate 44, a mounting agent 45, a chip 46, a bonding wire 47 and a molding resin 48. A chip 46 (NAND memory chip, controller chip, or the like) is fixed onto the substrate 44 using the mounting agent 45. A signal pad, a power supply pad and a grounding pad on the chip 46 are electrically connected to nodes on the substrate 44 where interconnects are present (bonding post 50 in FIG. 4A) using bonding wires 47 (gold wires or the like). In addition, the chip 46 and the bonding wires 47 are resin-sealed using a molding resin 48 and are thereby protected.

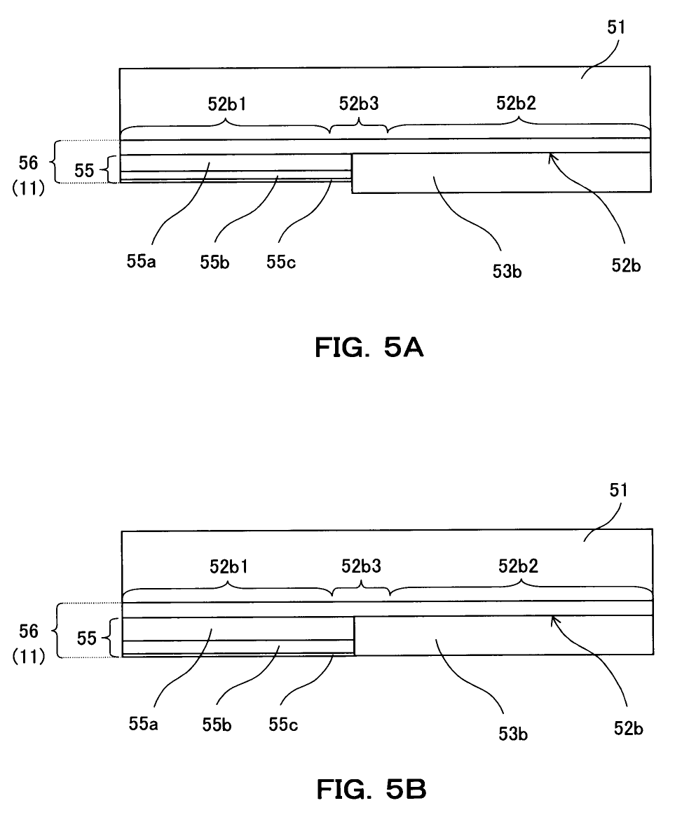

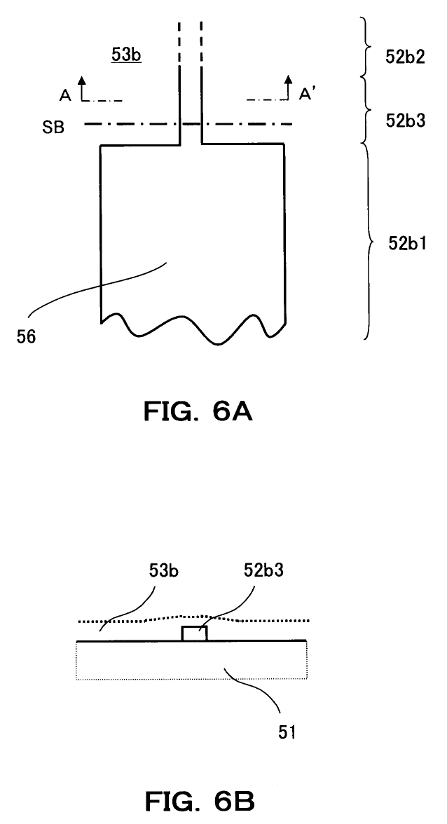

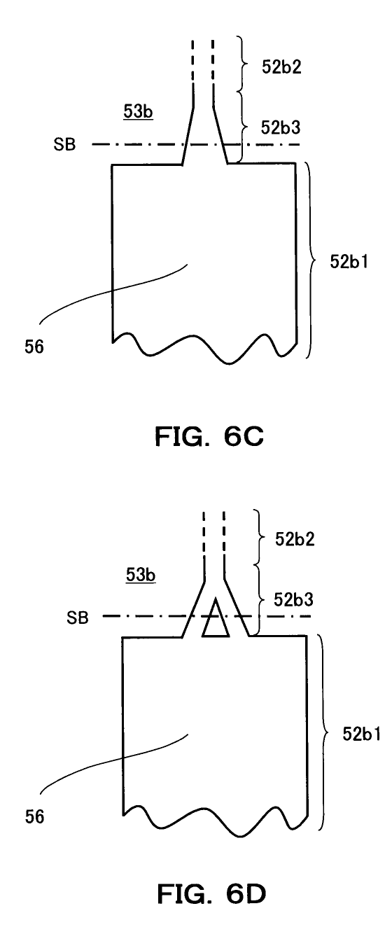

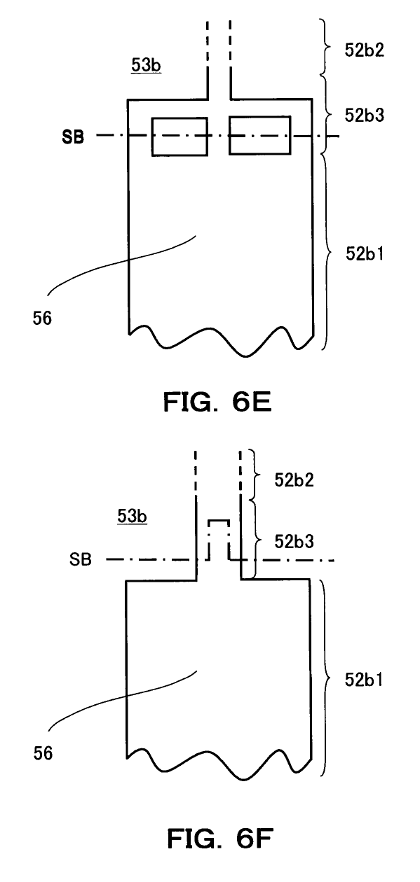

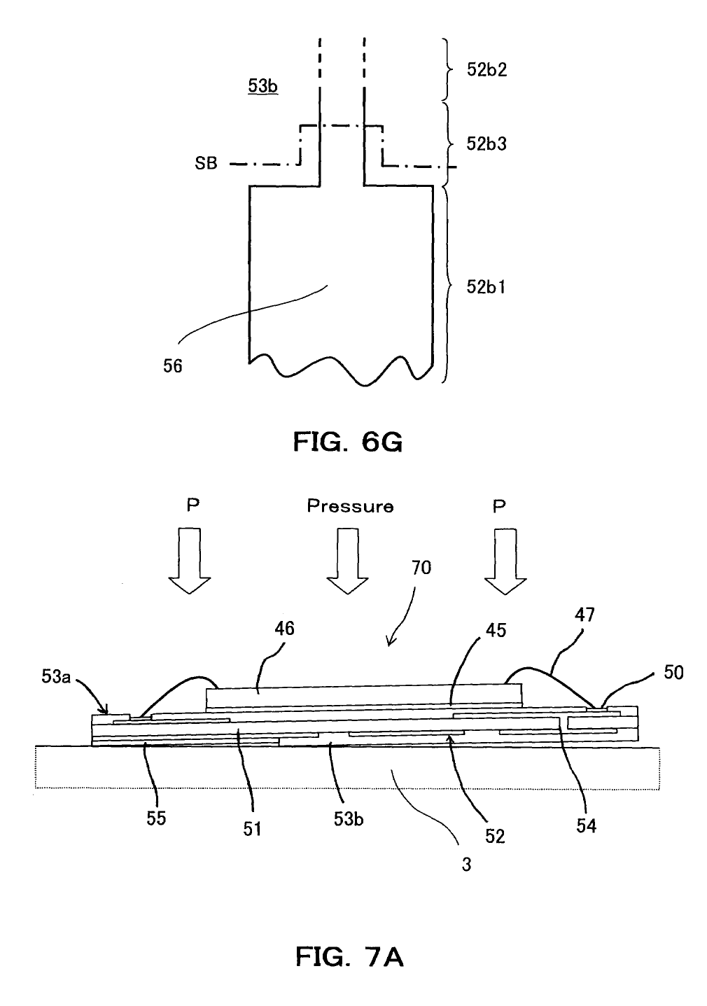

A detailed structure of the substrate package 42 is shown in FIG. 4A by taking out the package alone from FIG. 3. The substrate 44 is provided with a bonding post 50, a prepreg (substrate main body) 51, a copper interconnect 52 (52a, 52b), a solder resist 53 (53a, 53b), a through-hole 54, and a metal-plated layer 55. The prepreg 51 is provided with an inner surface (upper surface in the figure) internal to the semiconductor device, an outer surface (lower surface in the figure) external to the semiconductor device, and a through-hole 54. The copper interconnect 52 is formed of an internal wiring pattern 52a, an external wiring pattern 52b and a via 52c. As can be seen from FIG. 4A, the internal wiring pattern 52a is formed on the inner surface, the external wiring pattern 52b is formed on the outer surface, and the via 52c is formed in the through-hole 54 using the same interconnect material. The via 52c is used to electrically connect the internal wiring pattern 52a and the external wiring pattern 52b. In addition, the external wiring pattern 52b is formed mainly of a pattern for external terminals 52b1 and a pattern for non-external terminals 52b2. More specifically, as will be described later, the pattern for external terminals 52b1 and the pattern for non-external terminals 52b2 are coupled with each other through a coupling pattern 52b3 (see FIGS. 5A and 6A). The pattern for external terminals 52b1 is electrically connectable to the outside and constitutes part of the above-described external terminals 11. The pattern for non-external terminals 52b2 is covered with the solder resist 53 (53b). The solder resist 53 is a highly heat-resistant organic insulating material and is coated in order to protect the internal wiring pattern 52a and the pattern for non-external terminals 52b2. Hereinafter, a solder resist coated on the internal wiring pattern 52a will be referred to as an internal solder resist 53a and a solder resist coated on the external wiring pattern 52b will be referred to as an external solder resist 53b. The bonding post 50 is formed by applying gold plating to the internal wiring pattern 52a at an opening formed in a predetermined location of the internal solder resist 53a. As can be seen from the description given above, the bonding post 50 is electrically connected through the copper interconnect 52 to the pattern for external terminals 52b1 serving as part of the copper interconnect 52. A metal-plated layer 55 is formed on the pattern for external terminals 52b1 to constitute external terminals 56. Exchange of various signals between the card 10 and an external device and power supply to the card 10 from the outside are carried out by way of the external terminals 56 (11).

FIG. 4B shows a modification example of the device shown in FIG. 4A. The difference between the devices is the thickness of the metal-plated layer 55. As can be seen from this figure, a difference in step between the external terminals 56 and the external solder resist 53b is eliminated by increasing the thickness of this metal-plated layer 55.

FIG. 4C is another modification example of the device shown in FIG. 4A, illustrating a detailed structure of the substrate package 42 in which a plurality of NAND memory chips 46a and 46b and a controller chip 46c are stacked.

Note that in FIGS. 4B and 4C, the same circuit elements as those of FIG. 4A are denoted by like numerals and will not be explained again.

Now, various dimensions of the substrate package 42 illustrated in FIGS. 4A to 4C will be shown by way of example. The thickness of the substrate package 42 is 1.05 mm, wherein the thickness of the molding resin 48 accounts for 0.76 mm and the thickness of the substrate 44 accounts for 0.29 mm. In addition, the thicknesses of the chip 46 and the NAND memory chips 46a and 46b are 150 μm, the thickness of the controller chip 46c is 110 μm, and the thickness of the mounting agent 45 is 20 μm.

Next, a detailed explanation will be made, using FIG. 5A and FIG. 5B, to the fact that according to an embodiment of the present invention, it is possible to prevent chip cracks in a molding step.

FIG. 5A shows an enlarged cross-sectional view of a portion near a boundary between the external terminals 56 and the external solder resist 53b in FIG. 4C (or FIG. 4A). As can be seen from the figure, the external wiring pattern 52b (the pattern for external terminals 52b1, the pattern for non-external terminals 52b2, and the coupling pattern 52b3) is formed on the lower surface of the prepreg 51 in the figure. The external solder resist 53b is coated on the pattern for non-external terminals 52b2 and on part of the coupling pattern 52b3. Parts on which the external solder resist 53b is not coated (the pattern for external terminals 52b1 and part of the coupling pattern 52b3) and the later-described metal-plated layer 55 serve as the external terminals 56 of the semiconductor device. The metal-plated layer 55 constituting part of the external terminals 56 is formed of a three-layered structure. That is, a first metal-plated layer 55a is formed on the pattern for external terminals 52b1 and on part of the coupling pattern 52b3, a second metal-plated layer 55b is formed thereon, and a third metal-plated layer 55c is further formed thereon.

Now, an explanation will be made of types of metal which compose the respective metal-plated layers 55a, 55b and 55c.

The first metal-plated layer 55a uses nickel. Since nickel has a higher plating rate than hard nickel, it is possible to shorten a plating time. Note however that copper may be used in place of nickel. Use of copper plating has the advantage that a semiconductor device can be manufactured at a lower cost, compared with a case in which nickel is used.

The second metal-plated layer 55b uses hard nickel.

The third metal-plated layer 55c uses hard gold.

As can be seen from FIG. 5A, a difference in step between the external terminals 56 and the external solder resist 53b is reduced by increasing the thickness of the metal-plated layer 55.

Note that the difference in step between the external terminals 56 and the external solder resist 53b may be eliminated by further thickening the first metal-plated layer 55a. FIG. 5B shows a substrate package from which a difference in step has been eliminated in this way. FIG. 5B shows an enlarged cross-sectional view of a portion near a boundary between the external terminals 56 and the solder resist 53b shown in FIG. 4B. By eliminating a difference in step, it is possible to prevent the substrate 44 from sagging in a molding step, as will be described later.

Hereinafter, an explanation will be made specifically in this regard by citing numeric values as examples.

In FIG. 5A, the thickness of the external solder resist 53b is 10 to 20 μm (approximately 15 μm on average). The thickness of the first metal-plated layer 55a (nickel or copper) and the second metal-plated layer 55b (hard nickel) combined is 5 to 15 μm (approximately 10 μm on average). The thickness of the third metal-plated layer 55c (hard gold) is 0.5 to 1.5 μm (approximately 0.7 μm on average).

Accordingly, a difference in step between the external terminals 56 and the external solder resist 53b in FIG. 5A is approximately 4.3 μm on average. This value is approximately ¼ the value of a later-described example of a device subject to chip cracks that the present inventor has conceived earlier. The present inventor has confirmed that in this case, no chip cracks occur in a molding step. A possible reason for this is that, as will be described later, the flexure of the substrate and the chip caused when a molding pressure is applied reduces as the result of the difference in step being reduced.

Note that the external solder resist 53b is thinned by contriving the shape of the coupling pattern 52b3 and the like, in order to reduce the difference in step between the external terminals 56 and the external solder resist 53b. This will be explained using FIGS. 6A and 6B.

FIG. 6A is an enlarged plan view of a portion near a boundary between the external terminals 56 and the solder resist 53b. As is evident from the figure, the coupling pattern 52b3 is formed so that the width thereof is narrower than that of the external terminals 56. As described above, the coupling pattern 52b3 is used to couple the pattern for external terminals 52b1 and the pattern for non-external terminals 52b2 with each other. As indicated by the solder resist boundary (SB) in FIG. 6A, the external solder resist 53b is coated partway through the coupling pattern 52b3.

FIG. 6B is a cross-sectional view taken along the line A-A′ of FIG. 6A. The coupling pattern 52b3 is disposed on the prepreg 51. The external solder resist 53b is coated so as to cover the coupling pattern 52b3 and the prepreg 51. Since a gap between coupling patterns 52b3 is wide, it is possible to make the thickness of the external solder resist 53b smaller, compared with a case in which the width of the coupling pattern 52b3 is equal to the width of the pattern for external terminals 52b1.

Next, modification examples of FIG. 6A are shown in FIGS. 6C to 6G.

FIGS. 6C to 6E show examples of modification with respect to the shape of the coupling pattern 52b3. In contrast, FIGS. 6F and 6G show examples of modification with respect to the shape of the solder resist boundary (SB). In these modification examples, the solder resist boundary (SB) near the coupling pattern 52b3 is set back toward the pattern for non-external terminals 52b2 (upper side in the figure). By setting back the solder resist boundary in this way, it is possible to further decrease the thickness of the external solder resist 53b as viewed from the boundary between the pattern for external terminals 52b1 and the coupling pattern 52b3.

Note that in any of the examples shown in FIGS. 6C to 6G, the external solder resist 53b is coated partway through the coupling pattern 52b3.

As described heretofore, according to the present embodiment, it is possible to prevent chip cracks in a molding step without significantly affecting existing manufacturing equipment or manufacturing processes. Consequently, it is possible to provide an inexpensive substrate for semiconductor devices and an inexpensive semiconductor device.

Next, a method for manufacturing the NAND memory card 10 will be described. The devices shown in FIGS. 4A to 4C are almost the same with each other in terms of manufacturing method. Accordingly, an explanation will be made here while referring to FIG. 4C.

(1) A wafer containing a plurality of NAND memory chips and a wafer containing a plurality of controller chips are respectively back-lapped. Then, the wafers are diced and separated into a plurality of chips 46x (46a, 46b and 46c).
(2) There is prepared a plurality of substrates 44 on which a solder resist 53 is coated and in which a metal-plated layer 55 is formed. A mounting agent 45 is coated on each substrate 44 and a NAND memory chip 46a, which is one of the chips 46x, is mounted thereon.
(3) Hereinafter, an explanation will be made by focusing attention on one substrate 44. The mounting agent 45 is further coated on the chip 46a to mount the NAND memory chip 46b thereon.
(4) The mounting agent 45 is further coated on the chip 46b to mount the controller chip 46c thereon.
(5) Curing is performed to harden these mounting agents 45.
(6) Bonding is performed using bonding wires 47, to electrically connect the chips 46a, 46b and 46c to the bonding post 50 of the substrate 44. (Hereinafter, an assembly obtained in a process up to this point will be referred to as an intermediate NAND chip.)
(7) Molding is performed using a molding resin 48, to protect the chips 46a, 46b and 46c and the bonding wires 47. This molding step is carried out by arranging a plurality of intermediate NAND chips in a lower molding die, and then covering the lower molding die by an upper molding die and pressure-injecting a molten molding resin into the molding dies from one end thereof. At this time, the flexure of the substrate 44 hardly occurs and, therefore, no cracks occur in the respective chips 46a, 46b and 46c since molding is performed almost without causing the intermediate NAND chip to incline, as will be described later.
(8) In the molding step described in the preceding item, there is obtained an aggregate in which a plurality of substrate packages 42 are coupled with each other by a molding resin. This aggregate is cut by dicing into pieces, each being the size of one substrate package, thereby a plurality of substrate packages 42 being obtained (see FIG. 4A, etc.).
(9) Each substrate package 42 is housed in each case 40 for a NAND memory card and is bonded to the case using an adhesive 41 (see FIG. 3, etc.).
(10) Finally, a label 43 (12) is attached to the external solder resist 53b (see FIG. 1B, etc.).

Next, an explanation will be made to the fact that according to the present invention, it is possible to effectively prevent the occurrence of chip cracks also in the above-described molding step.

Note here that for ease of understanding, an explanation will be made of a case in which the device shown in FIG. 4A or 4B is fabricated.

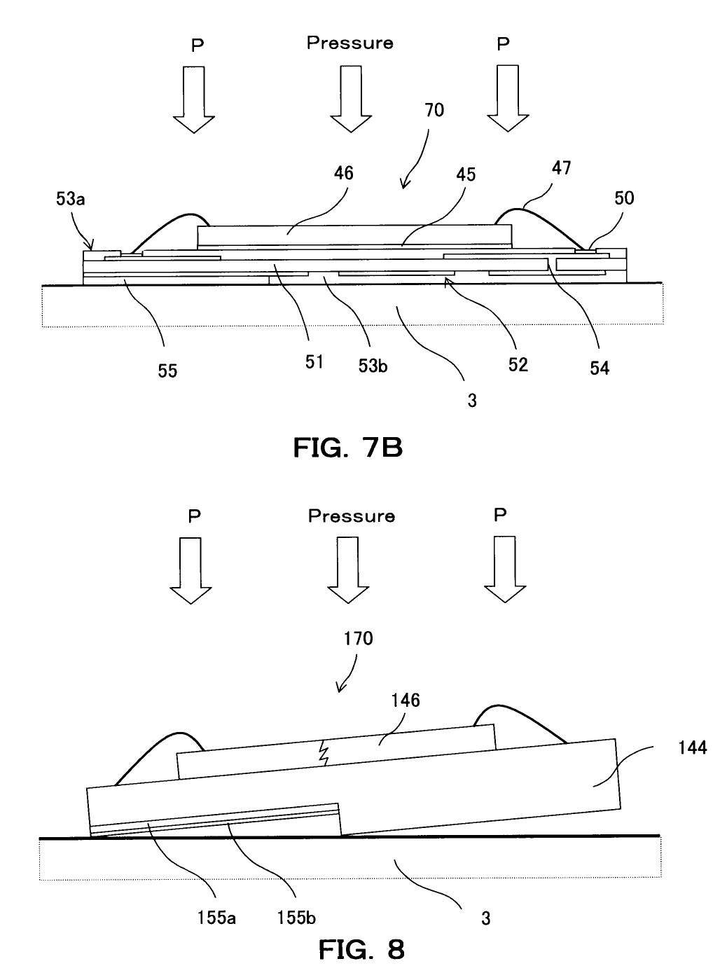

FIG. 7A shows a condition of the above-described intermediate NAND chip 70 in the molding step of the device shown in FIG. 4A. The intermediate NAND chip 70 is placed on a molding die 3 and the pressure of a pressure-injected molten molding resin is applied from above. As can be seen from FIG. 7A, there is a slight difference in step between the external terminals 56 and the external solder resist 53b. Consequently, the intermediate NAND chip 70 as a whole goes into a slightly incline state as the external terminal 56 side thereof is pressed on by this pressure. However, the flexure of the chip 46 and the substrate 44 is small and, therefore, the chip 46 is prevented from suffering chip cracks.

FIG. 7B shows a condition of the above-described intermediate NAND chip 70 in the molding step of the device shown in FIG. 4B. As in the case of FIG. 7A, this intermediate NAND chip 70 is placed on the molding die 3 and the pressure of a pressure-injected molten molding resin is applied from above. As can be seen from FIG. 7B, however, there is no difference in step between the external terminals 56 and the external solder resist 53b. Consequently, the intermediate NAND chip 70 does not incline at all and remains parallel with the molding die 3. Accordingly, the chip 46 and the substrate 44 do not sag at all and, therefore, the chip 46 is prevented from suffering chip cracks.

Next, a configuration, among the configurations that the present inventor has learned, in which chip cracks occur in a molding step is shown in FIG. 8 and will be explained specifically by citing illustrative numerical values.

The solder resist in the figure is coated to a thickness of approximately 20 μm. On the other hand, a metal-plated portion constituting part of external terminals is composed of a hard nickel-plated layer 155a and a hard gold-plated layer 155b formed thereon. The plating thickness of the hard nickel-plated layer 155a is 1.5 to 5 μm (approximately 3 μm on average) and the plating thickness of the hard gold-plated layer 155b is 0.3 μm or larger (0.5 μm on average). In order to suppress a cost increase due to plating, the hard nickel-plated layer 155a and the hard gold-plated layer 155b are thinly formed. Accordingly, there arises an difference in step of approximately 16.5 μm on average between the solder resist and the external terminals. Under the condition of such a large difference in step, a chip 146 and a substrate 144 sag significantly when a molding resin is pressure-injected into a molding die. As a result, chip cracks easily occur in the chip 146.

In particular, chip cracks easily occur when the chip is mounted on a border line between the plated-portion and the solder resist portion, as shown in FIG. 8. The present inventor has learned that an XD picture card can be mentioned as an example of such a case.

As has been described heretofore, according to the present invention, it is possible to prevent chip cracks in a molding step without significantly affecting existing manufacturing equipment or manufacturing processes. Consequently, it is possible to provide an inexpensive substrate for semiconductor devices and an inexpensive semiconductor device.

Additional advantages and modifications will readily occur to those skilled in the art.

Therefore, the invention in its broader aspects is not limited to the specific details and representative embodiments shown and described herein.

Accordingly, various modifications may be made without departing from the spirit or scope of the general inventive concepts as defined by the appended claims and their equivalents.

1. A semiconductor device comprising:
a substrate main body provided with an inner surface internal to said semiconductor device and an outer surface external to said semiconductor device opposed to each other;
an external wiring pattern having a pattern for non-external terminals covered with an insulating material and a pattern for external terminals electrically conductive to the outside formed at least on said outer surface of said substrate main body using a conductive material and electrically connected to each other;
an insulating film for covering said pattern for non-external terminals of said external wiring pattern;
a metal-plated layer adapted to constitute external terminals in conjunction with said pattern for external terminals and formed on said pattern for external terminals of said external wiring pattern, so as to reduce or eliminate a difference in step with respect to said insulating film;
a semiconductor chip mounted on said inner surface of said substrate main body; and
a molding resin for molding said inner surface of said substrate main body along with said semiconductor chip.

2. The semiconductor device according to claim 1, wherein said metal-plated layer is formed as a stacked body composed of a plurality of plated layers.

3. The semiconductor device according to claim 2, wherein said semiconductor chip is formed of a plurality of stacked semiconductor chips.

4. The semiconductor device according to claim 3, wherein said external wiring pattern has a coupling pattern, the width of which is narrower than the width of said pattern for external terminals, between said pattern for non-external terminals and said pattern for external terminals to provide coupling therebetween, and said insulating film covers from said pattern for non-external terminals partway through said coupling pattern.

5. The semiconductor device according to claim 4, wherein said stacked body includes:
a first metal-plated layer made of nickel or copper and formed on said pattern for external terminals;
a second metal-plated layer made of hard nickel and formed on said first metal-plated layer; and
a third metal-plated layer made of hard gold and formed on said second metal-plated layer.

6. The semiconductor device according to claim 4, wherein said insulating film is concavely formed so as to extend inward from the leading surface thereof facing said external terminals and has a cutout whereby part of said coupling pattern is exposed.

7. The semiconductor device according to claim 2, wherein said external wiring pattern has a coupling pattern, the width of which is narrower than the width of said pattern for external terminals, between said pattern for non-external terminals and said pattern for external terminals to provide coupling therebetween, and said insulating film covers from said pattern for non-external terminals partway through said coupling pattern.

8. The semiconductor device according to claim 7, wherein said stacked body includes:
a first metal-plated layer made of nickel or copper and formed on said pattern for external terminals;
a second metal-plated layer made of hard nickel and formed on said first metal-plated layer; and
a third metal-plated layer made of hard gold and formed on said second metal-plated layer.

9. The semiconductor device according to claim 7, wherein said insulating film is concavely formed so as to extend inward from the leading surface thereof facing said external terminals and has a cutout whereby part of said coupling pattern is exposed.

10. The semiconductor device according to claim 2, wherein said stacked body includes:
a first metal-plated layer made of nickel or copper and formed on said pattern for external terminals;
a second metal-plated layer made of hard nickel and formed on said first metal-plated layer; and
a third metal-plated layer made of hard gold and formed on said second metal-plated layer.

11. The semiconductor device according to claim 1, wherein said semiconductor chip is formed of a plurality of stacked semiconductor chips.

12. The semiconductor device according to claim 11, wherein said external wiring pattern has a coupling pattern, the width of which is narrower than the width of said pattern for external terminals, between said pattern for non-external terminals and said pattern for external terminals to provide coupling therebetween, and said insulating film covers from said pattern for non-external terminals partway through said coupling pattern.

13. The semiconductor device according to claim 12, wherein said insulating film is concavely formed so as to extend inward from the leading surface thereof facing said external terminals and has a cutout whereby part of said coupling pattern is exposed.

14. The semiconductor device according to claim 1, wherein said external wiring pattern has a coupling pattern, the width of which is narrower than the width of said pattern for external terminals, between said pattern for non-external terminals and said pattern for external terminals to provide coupling therebetween, and said insulating film covers from said pattern for non-external terminals partway through said coupling pattern.

15. The semiconductor device according to claim 14, wherein said insulating film is concavely formed so as to extend inward from the leading surface thereof facing said external terminals and has a cutout whereby part of said coupling pattern is exposed.

16. A method for manufacturing a semiconductor device, comprising:
preparing a substrate main body provided with an inner surface internal to said semiconductor device and an outer surface external to said semiconductor device opposed to each other;
forming an external wiring pattern having a pattern for non-external terminals covered with an insulating material and a pattern for external terminals electrically conductive to the outside, said patterns being electrically connected to each other, at least on said outer surface of said substrate main body using a conductive material;
covering said pattern for non-external terminals of said external wiring pattern with an insulating film;
forming a metal-plated layer for reducing or eliminating a difference in step with respect to said insulating film on said pattern for external terminals of said external wiring pattern;
mounting a semiconductor chip on said inner surface of said substrate main body; and
molding said inner surface of said substrate main body along with said semiconductor chip using a molding resin.

17. The method for manufacturing a semiconductor device according to claim 16, wherein said metal-plated layer is formed by laminating a plurality of plated layers.

18. The method for manufacturing a semiconductor device according to claim 17, wherein said plurality of plated layers are formed by forming a first metal-plated layer made of nickel or copper on said pattern for external terminals, forming a second metal-plated layer made of hard nickel on said first metal-plated layer, and forming a third metal-plated layer made of hard gold on said second metal-plated layer.

19. The method for manufacturing a semiconductor device according to claim 16, wherein an assembly in which a plurality of semiconductor chips are stacked is used as said semiconductor chip.

20. The method for manufacturing a semiconductor device according to claim 16, wherein a coupling pattern, the width of which is narrower than the width of said pattern for external terminals, is formed as part of said external wiring pattern between said pattern for non-external terminals and said pattern for external terminals to provide coupling therebetween, and said insulating film is formed so as to cover from said pattern for non-external terminals partway through said coupling pattern.
